(19) United States
(12) Patent Application Publication
(10) Pub. No.: US 2007/0158537 A1
(43) Pub. Date: Jul. 12, 2007

(54) Package for Image Sensor and Identification Module

(75) Inventor: Peng-Chia Kuo, Taipei (TW)

Correspondence Address: LAW OFFICES OF LAI AND ASSOCIATES, P.C., 5800 RANCHESTER STE 200, HOUSTON, TX, 77036, US

(73) Assignee: Nanogate Optoelectronic Robot, Inc., Taipei (TW)

(21) Appl. No.: 11/306,759

(22) Filed: Jan. 10, 2006

(51) Int. Cl. H01L 27/00; H01J 5/02; H01J 40/14

(52) U.S. Cl. 250/239; 250/208.1

(57) ABSTRACT

A package for an image sensor and an identification module is disclosed. The package for image sensor and identification module includes a substrate having an image sensing device, a central processor and a memory thereon and a holder having a window which is onto the image sensing device, wherein the holder is mounted on the substrate and seals the image sensing device, the central processor and the memory.

### FIELD OF THE INVENTION

The present invention relates to a package for an image sensor and an identification module and, more particularly, to use a holder having a window that is applied to the package for the image sensor and the identification module.

### BACKGROUND OF THE INVENTION

There are many differences between the package for a conventional image sensing device and the integrated circuit (IC) package. Generally speaking, the IC package does not need to concern the image receiving, and a molding compound is often used to fill or cover for an IC chip. The package for the image sensing device is to use a transparent glass to cover the image sensing device. As shown in FIG. 1, an image sensing device 11 which is placed upon a substrate 10 is mounted by a welding wire 14 on the substrate 11. A sheet glass 12 and a dam 13 are then used to seal the image sensing device 11. The sheet glass 12 is combined with the dam 13 via glue and the dam 13 is also mounted on the substrate 10 that causes shortcomings of the complication in process and poor reliability.

In addition, the image sensing device 111 covered by the sheet glass 12 may be influenced by dust. In other words, the image quality will be decreased when dust is stuck on the sheet glass 12.

The inside of the package for the conventional image sensor does not have a Micro-Controlling Unit (MCU) and a memory, therefore, the MCU must be bought before assembling a complete module with MCU that increases cost and volumes.

To overcome the foregoing shortcomings of the prior arts, the inventor of the present invention based on years of experience on related research and development of the package for the image sensor invents a holder having a window that is applied to a package for an image sensor and an identification module.

### SUMMARY OF THE INVENTION

Briefly, the object of the present invention is to provide a holder having a window that is applied to a package for an image sensor and an identification module, so as to improve the image sensing quality and reduce process steps. Moreover, the goals of increased function, and reduced volume and cost can be achieved.

In accordance with the present invention, the package for the image sensor and the identification module comprises a substrate and a holder. The substrate has an image sensing device, a central processor and a memory. The purpose of the image sensing device is to sense an image. The holder is mounted on the substrate to seal the image sensing device. The holder has a window which is upon the image sensing device.

Furthermore, according to the present invention, another package for an image sensor and an identification module comprises a substrate and a holder. The substrate has an image sensing device and an identification module. The image sensing device is to sense an image and the image is identified by the identification module. The holder is mounted on the substrate to seal the image sensing device and the identification module. The holder has a window which is upon the image sensing device.

Other features and advantages of the present invention and variations thereof will become apparent from the following description, drawings, and claims.

### BRIEF DESCRIPTION OF THE DRAWINGS

FIG. 1 is a schematic diagram illustrating a conventional package for an image sensor and an identification module;

FIG. 2A is a schematic diagram illustrating a package for an image sensor and an identification module according to an embodiment of the present invention;

FIG. 2B is a top plan view illustrating a package for an image sensor and an identification module according to an embodiment of the present invention;

FIG. 3 is a schematic diagram illustrating a multiple chip module (MCM) of the package for the image sensor and the identification module according to an embodiment of the present invention;

FIG. 4A is a schematic diagram illustrating the holder of the package for the image sensor and the identification module according to a preferred embodiment of the present invention; and

FIG. 4B is a schematic diagram illustrating the holder of the package for the image sensor and the identification module according to a preferred embodiment of the present invention.

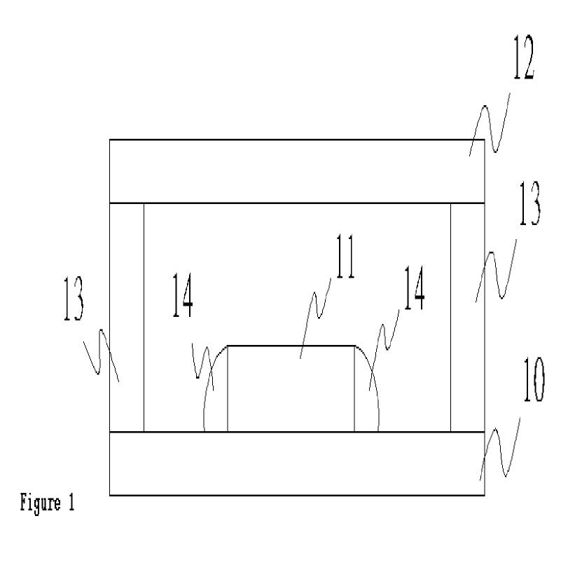

### DETAILED DESCRIPTION OF THE PREFERRED EMBODIMENTS

To make it easier for understanding the objective of the invention, its innovative features and performance, a detailed description and technical characteristics of a package for an image sensor and an identification module are described together with the drawings as follows.

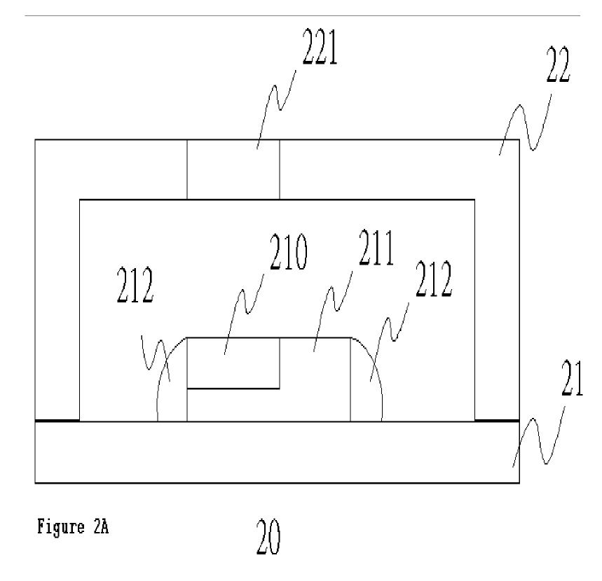

Referring to FIG. 2A and FIG. 2B, a schematic diagram and a top plan view illustrate a package for an image sensor and an identification module. The package for the image sensor and the identification module 20 comprises a substrate 21 and a holder 22. A System-on-Chip 211 having an image sensing device 210 is set on the substrate 21. The System-on-Chip 211 is mounted by a welding wire 212 on the substrate 21. The holder 22 is mounted by glue on the substrate 21 to seal the System-on-Chip 211. The holder 210 has a window 221 which is upon the image sensing device 210 to help the image sensing device 210 to receive an image. The holder 210 is an opaque material. The window 221 is glass or a transparent plastic material and is connected to the holder 22 through glue. The transparent plastic material can be made double color injection molding. The window 221 is an optical element like a lens and is connected to the holder 22 by using glue. Besides, the System-on-Chip 211 can further comprise an identification module to identify the image received by the image sensing device 210.

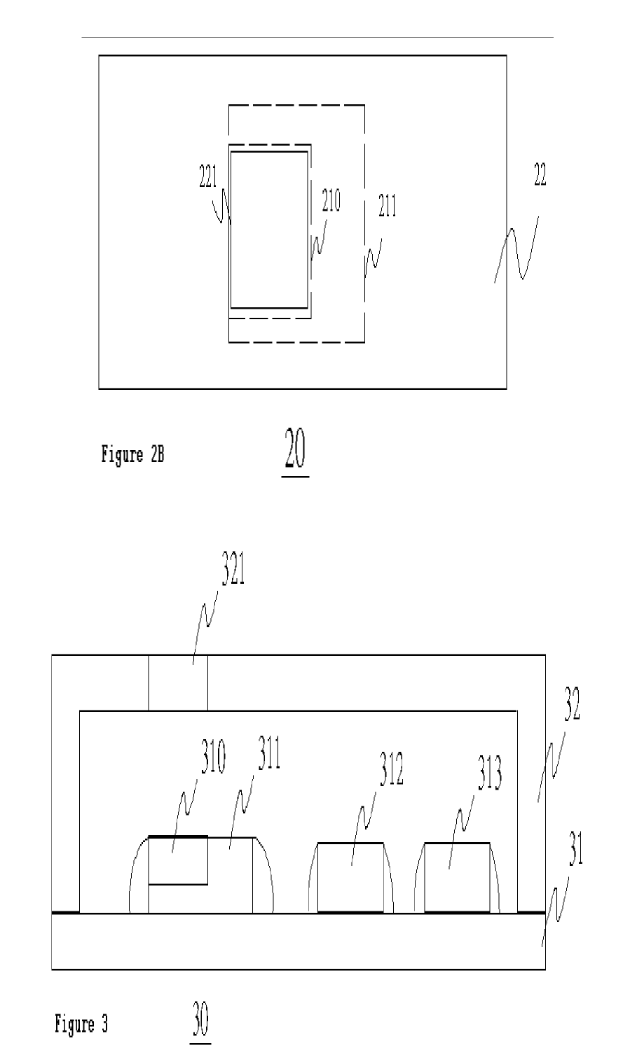

Referring to FIG. 3, a schematic diagram illustrates a multiple chip module (MCM) of the package for the image sensor and the identification module according to an embodiment of the present invention. The MCM 30 comprises a substrate 31 and a holder 32. A System-on-Chip 311 having an image sensing device 310, a memory 312 and a central processor 313 are set on the substrate 31. These components are mounted by welding wires on the substrate 31. The holder 32 is combined with the substrate 31 via glue. The holder 32 has a window 321 which is upon the image sensing device 310 to help the image sensing device 310 to receive an image. An identification action is implemented by the central processor 313 based on an image identification program and an identification parameter stored in the memory 312. The holder 32 is an opaque material. The window 321 is glass or a transparent plastic material and is connected to the holder 32 through glue. The transparent plastic material can be made by double color injection molding. The window 321 is an optical element like lens and is connected to the holder 32 by using glue.

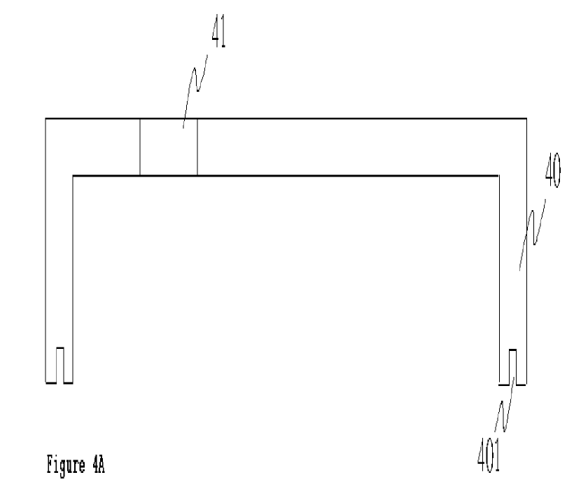

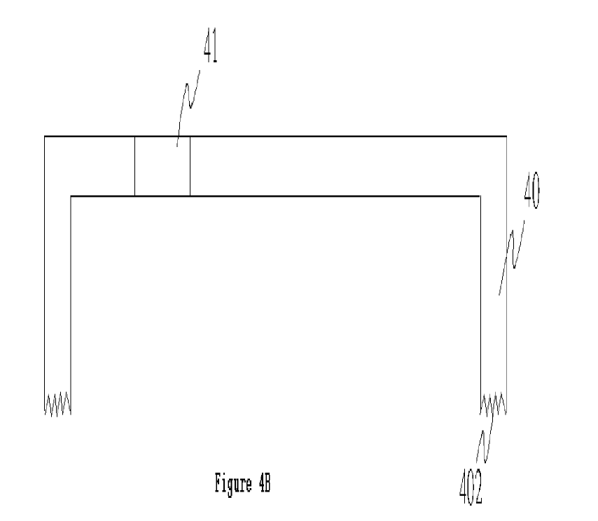

Referring to FIG. 4A and FIG. 4B, schematic diagrams illustrate the holder of the package for the image sensor and the identification module according to preferred embodiments of the present invention. A faying surface of a holder 40 having a window 41 for mounting on a substrate (not shown) has a notch 401 or a rough surface 402 to increase the area for contacting the glue. Therefore, the reliability for the holder mounting on the substrate can be improved.

Although the features and advantages of the embodiments according to the preferred invention are disclosed, it is not limited to the embodiments described above, but encompasses any and all modifications and changes within the spirit and scope of the following claims.

What is claimed is:

1. A package for an image sensor and an identification module, comprising:
a substrate having an image sensing device, a central processor and a memory, said image sensing device for receiving an image; and
a holder for mounting on said substrate to seal said image sensing device, said central processor and said memory;
wherein said holder has a window and said window is located upon said image sensing device.

2. The package for an image sensor and an identification module of claim 1, wherein said package for an image sensor and an identification module further comprises an identification module for identifying said image.

3. The package for an image sensor and an identification module of claim 1, wherein said window is glass, a transparent plastic or an optical element, said window is combined with said holder via an adhesive.

4. The package for an image sensor and an identification module of claim 1, wherein said window is a transparent plastic, said holder and said window are made by double color injection molding.

5. The package for an image sensor and an identification module of claim 1, wherein a faying surface of said holder for mounting on said substrate has a notch or a rough surface.

6. The package for an image sensor and an identification module of claim 1, wherein said substrate further comprises a System-on-Chip, said image sensing device is a portion of said System-on-Chip.

7. The package for an image sensor and an identification module of claim 2, wherein said substrate further comprises a System-on-Chip, said image sensing device and said identification module are a portion of said System-on-Chip.

8. The package for an image sensor and an identification module of claim 1, wherein said central processor and said memory are to identify said image.

9. The package for an image sensor and an identification module of claim 1, wherein said central processor and said memory are combined with said image sensing device to be a multiple chip module.

10. The package for an image sensor and an identification module of claim 2, wherein said central processor, said memory and said identification are combined with said image sensing device to be a multiple chip module.
